(19) United States
(12) Patent Application Publication
(10) Pub. No.: US 2012/0007257 A1
(43) Pub. Date: Jan. 12, 2012

(54) SEMICONDUCTOR DEVICE AND MANUFACTURING METHOD THEREOF

(75) Inventor: Kotaro NOMURA, Toyama (JP)

(73) Assignee: PANASONIC CORPORATION, Osaka (JP)

(21) Appl. No.: 13/243,011

(22) Filed: Sep. 23, 2011

Related U.S. Application Data
(63) Continuation of application No. PCT/JP2010/000541, filed on Jan. 29, 2010.

(30) Foreign Application Priority Data
Apr. 3, 2009 (JP) 2009-091564

(51) Int. Cl. H01L 23/522; H01L 21/768

(52) U.S. Cl. 257/774; 438/624; 257/E23.145; 257/E21.577

(57) ABSTRACT

A semiconductor device includes: a first insulating film formed on a substrate and having a first interconnect; a second insulating film as a liner film formed on the first insulating film and the first interconnect so as to contact the first insulating film; and a third insulating film formed on the second insulating film so as to contact the second insulating film. The second insulating film includes pores.

### CROSS-REFERENCE TO RELATED APPLICATION

This is a continuation of PCT International Application PCT/JP2010/000541 filed on Jan. 29, 2010, which claims priority to Japanese Patent Application No. 2009-091564 filed on Apr. 3, 2009. The disclosures of these applications including the specifications, the drawings, and the claims are hereby incorporated by reference in their entirety.

### BACKGROUND

The present invention relates to semiconductor devices and manufacturing methods thereof.

With a recent increase in integration density of semiconductor integrated circuits, interconnect patterns have been increased in density, causing an increase in parasitic capacitance between interconnects. Since increased parasitic capacitance between interconnects causes an interconnect delay of signals, reduction in parasitic capacitance between interconnects is an important issue for semiconductor integrated circuits that are required to operate at a high speed. Thus, the relative dielectric resistance of an insulating film between interconnects is reduced in order to reduce the parasitic capacitance between interconnects.

Conventionally, a silicon oxide film (a SiO₂ film) having a relative dielectric constant of 3.9-4.2 or a SiO₂ film containing fluorine (F) having a relative dielectric constant of 3.5-3.8 has been commonly used as an insulating film between interconnects. Recently, a SiOC film having a relative dielectric constant of 3.0 or less has been used as an insulating film between interconnects in some of semiconductor integrated circuits.

It is proposed to use a porous silica film as an insulating film between interconnects in order to further reduce the parasitic capacitance between interconnects. Since the porous silica film has low mechanical strength, it is proposed to perform a curing process on the porous silica film by ultraviolet (UV) radiation as a method to improve the mechanical strength of the porous silica film. However, this method has the following problem. In the curing process, UV light that has transmitted through the porous silica film enters a film formed below the porous silica film, thereby degrading the film formed below the porous silica film. As a solution to this problem, a technique has been proposed in which a UV transmission suppressing film is provided between the porous silica film and the film formed below the porous silica film, in order to improve the mechanical strength of the porous silica film while suppressing degradation of the film formed below the porous silica film (see, e.g., Japanese Patent Publication No. 2008-21800).

A method for manufacturing a conventional semiconductor device described in Japanese Patent Publication No. 2008-21800 will be described below with reference to FIGS. 5A-5C. FIGS. 5A-5C are cross-sectional views sequentially showing the steps of the method for manufacturing the conventional semiconductor device.

First, as shown in FIG. 5A, a SiOC film 101 having a thickness of 130 nm is formed on a substrate 100. Next, a UV transmission suppressing film 102, which is a SiCN film having a thickness of 30 nm, is formed on the SiOC film 101, and a porous silica film 103 having a thickness of 130 nm is formed on the UV transmission suppressing film 102. Then, the porous silica film 103 is cured by UV radiation.

As shown in FIG. 5B, a hole 104 is formed by etching so as to extend through the porous silica film 103, the UV transmission suppressing film 102, and the SiOC film 101 and to expose the upper surface of the substrate 100.

As shown in FIG. 5C, an interconnect groove is formed in the porous silica film 103 by etching. In this manner, a via hole is formed in the SiOC film 101 and the UV transmission suppressing film 102, and an interconnect groove communicating with the via hole is formed in the porous silica film 103.

Then, a barrier metal film is formed on the bottom and side surfaces of the via hole, on the bottom and side surfaces of the interconnect groove, and on the porous silica film 103. Subsequently, a conductive film is formed above the porous silica film 103 so as to fill the via hole and the interconnect groove. Those portions of the barrier metal and the conductive film which are formed outside the interconnect groove are then removed by a chemical mechanical polishing (CMP) method, thereby forming a via 105 and an interconnect 106. The via 105 has a barrier metal 105a formed on the bottom and side surfaces of the via hole, and a conductive film 105b embedded in the via hole with the barrier metal 105a interposed therebetween. The interconnect 106 has a barrier metal 106a formed on the bottom and side surfaces of the interconnect groove, and a conductive film 106b embedded in the interconnect groove with the barrier metal 106a interposed therebetween.

The conventional semiconductor device is manufactured in this manner.

In order to further reduce the parasitic capacitance between interconnects, it is also proposed to use a SiOC film having a reduced relative dielectric constant of 2.5 or less as an insulating film between interconnects. Such a SiOC film having a reduced relative dielectric constant of 2.5 or less is formed as follows. After forming a SiOC film having a relative dielectric constant of 3.0 or less, the SiOC film is cured by UV radiation, thereby forming the SiOC film having a reduced relative dielectric constant of 2.5 or less.

### SUMMARY

However, after intensive studies, the inventor of the present application has found that semiconductor devices have the following problems if such a SiOC film having a reduced relative dielectric constant of 2.5 or less is used as an insulating film between interconnects.

In the UV curing process of the SiOC film, UV light that has transmitted through the SiOC film enters a film formed below the SiOC film. Thus, the film formed below the SiOC film is also subjected to the UV curing process.

For example, in the case where the film formed below the SiOC film is a SiC film, the relative dielectric constant of the SiC film is increased by the UV curing process (see the left side of Table 1 described later). As a result, the capacitance between interconnects is increased, whereby an interconnect delay is increased.

Moreover, in this case, high tensile stress is generated in the SiC film (see the left side of Table 3 described later). Such high tensile stress in the SiC film reduces adhesion between the SiC film and an interconnect formed below the SiC film, which causes electromigration (EM) in the interconnect, thereby reducing interconnect reliability.

As described above, if the UV light that has transmitted through the SiOC film enters the film (e.g., the SiC film) formed below the SiOC film in the UV curing process of the SiOC film, and the film formed below the SiOC film is also subjected to the UV curing process, the interconnect delay is increased, and the interconnect reliability is reduced.

In view of the above problems, it is an object of the present invention to prevent an increase in interconnect delay and to suppress reduction in interconnect reliability.

In order to achieve the above object, a semiconductor device according to one aspect of the present invention includes: a first insulating film formed on a substrate and having a first interconnect; a second insulating film formed on the first insulating film and the first interconnect; and a third insulating film formed on the second insulating film, wherein the second insulating film includes pores.

According to the semiconductor device of the one aspect of the present invention, no unnecessary bonds (e.g., Si—O bonds) are formed near an upper surface of the second insulating film in a curing process of the third insulating film. This can prevent an increase in relative dielectric constant of the second insulating film, and therefore, can prevent an increase in capacitance between interconnects, and thus can prevent an increase in interconnect delay.

As described above, no unnecessary bonds (e.g., Si—O bonds) are formed near the upper surface of the second insulating film in the curing process of the third insulating film. This can suppress generation of high tensile stress in the second insulating film, and therefore, can suppress reduction in adhesion between the second insulating film and the first interconnect, and thus can suppress reduction in interconnect reliability.

Moreover, since the second insulating film includes the pores, the relative dielectric constant of the second insulating film can be reduced, whereby the capacitance between interconnects can be reduced.

In the semiconductor device of the one aspect of the present invention, it is preferable that the third insulating film be made of SiOC, and that the third insulating film have a relative dielectric constant of 2.5 or less.

In the semiconductor device of the one aspect of the present invention, it is preferable that the semiconductor device further include a fourth insulating film formed on the third insulating film, a via be formed in both the second insulating film and a lower region of the third insulating film, a second interconnect be formed in both an upper region of the third insulating film and the fourth insulating film, and the first interconnect be electrically connected to the second interconnect through the via.

In the semiconductor device of the one aspect of the present invention, it is preferable that the second insulating film be made of SiC.

In the semiconductor device of the one aspect of the present invention, it is preferable that the second insulating film have a relative dielectric constant of 4.0 or less.

In the semiconductor device of the one aspect of the present invention, it is preferable that the second insulating film have a substantially constant carbon content rate in a thickness direction.

In the semiconductor device of the one aspect of the present invention, it is preferable that the second insulating film have a substantially constant oxygen content rate in a thickness direction.

In the semiconductor device of the one aspect of the present invention, it is preferable that the second insulating film have a density of about 1.2 g/cm³ to about 2.0 g/cm³, both inclusive.

In the semiconductor device of the one aspect of the present invention, it is preferable that a Si—CH₃/Si—C ratio in the second insulating film be in a range of 0.02 to 0.10, both inclusive.

In the semiconductor device of the one aspect of the present invention, it is preferable that the second insulating film be made of SiCO, and a Si—O/Si—C ratio in the second insulating film be 1.0 or more.

In the semiconductor device of the one aspect of the present invention, it is preferable that the second insulating film be made of SiCN.

In order to achieve the above object, a method for manufacturing a semiconductor device according to another aspect of the present invention includes the steps of: (a) forming on a substrate a first insulating film having a first interconnect; (b) forming on the first insulating film and the first interconnect a second insulating film formation film containing porogen; (c) forming a third insulating film on the second insulating film formation film; and (d) performing a curing process on the third insulating film, wherein in the step (d), the curing process is performed on the second insulating film formation film to form a second insulating film having pores formed by eliminating the porogen contained in the second insulating film formation film.

According to the method of the another aspect of the present invention, no unnecessary bonds (e.g., Si—O bonds) are formed near an upper surface of the second insulating film in the curing process. This can prevent an increase in relative dielectric constant of the second insulating film, and therefore, can prevent an increase in capacitance between interconnects, and thus can prevent an increase in interconnect delay.

As described above, no unnecessary bonds (e.g., Si—O bonds) are formed near the upper surface of the second insulating film in the curing process. This can suppress generation of high tensile stress in the second insulating film, and therefore, can suppress reduction in adhesion between the second insulating film and the first interconnect, and thus can suppress reduction in interconnect reliability.

Moreover, in the curing process, porogen contained in the second insulating film formation film is eliminated, whereby the second insulating film includes the pores formed by the elimination of porogen. Thus, the relative dielectric constant of the second insulating film can be reduced, whereby the capacitance between interconnects can be reduced.

In the method of the another aspect of the present invention, it is preferable that the third insulating film be made of SiOC, and in the step (d), a relative dielectric constant of the third insulating film be reduced from that of the third insulating film in the step (c), and the relative dielectric constant of the third insulating film in the step (d) be 2.5 or less.

In the method of the another aspect of the present invention, it is preferable that the step (d) be a step of irradiating the third insulating film with UV light.

In this case, even if, e.g., the UV light transmits through the third insulating film and enters the second insulating film formation film in the curing process, UV energy that has entered the second insulating film formation film can be consumed by eliminating porogen contained in the second insulating film formation film. Thus, no unnecessary bonds (e.g., Si—O bonds) are formed near the upper surface of the second insulating film by the UV light that has entered the second insulating film formation film.

In the method of the another aspect of the present invention, it is preferable that the step (d) be a step of irradiating the third insulating film with electron beams.

In this case, even if, e.g., the electron beams transmit through the third insulating film and enter the second insulating film formation film in the curing process, electron beam energy that has entered the second insulating film formation film can be consumed by eliminating porogen contained in the second insulating film formation film. Thus, no unnecessary bonds (e.g., Si—O bonds) are formed near the upper surface of the second insulating film by the electron beams that have entered the second insulating film formation film.

In the method of the another aspect of the present invention, it is preferable that the step (d) be a step of exposing the third insulating film to a heat source.

In this case, even if, e.g., heat supplied to the third insulating film is conducted to the second insulating film formation film in the curing process, thermal energy that has been conducted to the second insulating film formation film can be consumed by eliminating porogen contained in the second insulating film formation film. Thus, no unnecessary bonds (e.g., Si—O bonds) are formed near the upper surface of the second insulating film by the heat that has been conducted to the second insulating film formation film.

In the method of the another aspect of the present invention, it is preferable that method further include the steps of: (e) after the step (d), forming a fourth insulating film on the third insulating film; and (f) forming a via in a via hole formed in both the second insulating film and a lower region of the third insulating film, and forming a second interconnect in an interconnect groove formed in both an upper region of the third insulating film and the fourth insulating film.

In the method of the another aspect of the present invention, it is preferable that the second insulating film be made of SiC.

In the method of the another aspect of the present invention, it is preferable that in the step (d), a relative dielectric constant of the second insulating film be reduced from that of the second insulating film formation film, and the relative dielectric constant of the second insulating film be 4.0 or less.

In the method of the another aspect of the present invention, it is preferable that in the step (d), the second insulating film be formed so as to have a substantially constant carbon content rate in a thickness direction.

In the method of the another aspect of the present invention, it is preferable that in the step (d), the second insulating film be formed so as to have a substantially constant oxygen content rate in a thickness direction.

In the method of the another aspect of the present invention, it is preferable that in the step (d), a C/Si composition ratio in the second insulating film be reduced from that in the second insulating film formation film by 0.5% or more.

In the method of the another aspect of the present invention, it is preferable that the second insulating film be made of SiCO, and in the step (d), an O/Si composition ratio in the second insulating film be increased from that in the second insulating film formation film by 2.0% or more.

In the method of the another aspect of the present invention, it is preferable that the second insulating film be made of SiCN, and in the step (d), an N/Si composition ratio in the second insulating film be reduced from that in the second insulating film formation film by 2.0% or more.

As described above, according to the semiconductor device of the one aspect of the present invention and the method of the another aspect of the present invention, no unnecessary bonds (e.g., Si—O bonds) are formed near the upper surface of the second insulating film in the curing process. This can prevent an increase in relative dielectric constant of the second insulating film, and therefore, can prevent an increase in capacitance between interconnects, and thus can prevent an increase in interconnect delay.

As described above, no unnecessary bonds (e.g., Si—O bonds) are formed near the upper surface of the second insulating film in the curing process. This can suppress generation of high tensile stress in the second insulating film, and therefore, can suppress reduction in adhesion between the second insulating film and the first interconnect, and thus can suppress reduction in interconnect reliability.

Moreover, in the curing process, porogen contained in the second insulating film formation film is eliminated, whereby the second insulating film includes the pores formed by the elimination of porogen. Thus, the relative dielectric constant of the second insulating film can be reduced, whereby the capacitance between interconnects can be reduced.

### BRIEF DESCRIPTION OF THE DRAWINGS

FIG. 1 is a cross-sectional view showing a configuration of a semiconductor device according to an embodiment of the present invention.

FIGS. 2A-2C are cross-sectional views sequentially showing the steps of a method for manufacturing the semiconductor device according to the embodiment of the present invention.

FIGS. 3A-3C are cross-sectional views sequentially showing the steps of the method for manufacturing the semiconductor device according to the embodiment of the present invention.

FIG. 4A is a graph showing the relation between the respective content rates of C and O and the depth after a UV curing process of a SiC film containing no porogen, and FIG. 4B is a graph showing the relation between the respective content rates of C and O and the depth after the UV curing process of a SiC film containing porogen.

FIGS. 5A-5C are cross-sectional views sequentially showing the steps of a method for manufacturing a conventional semiconductor device.

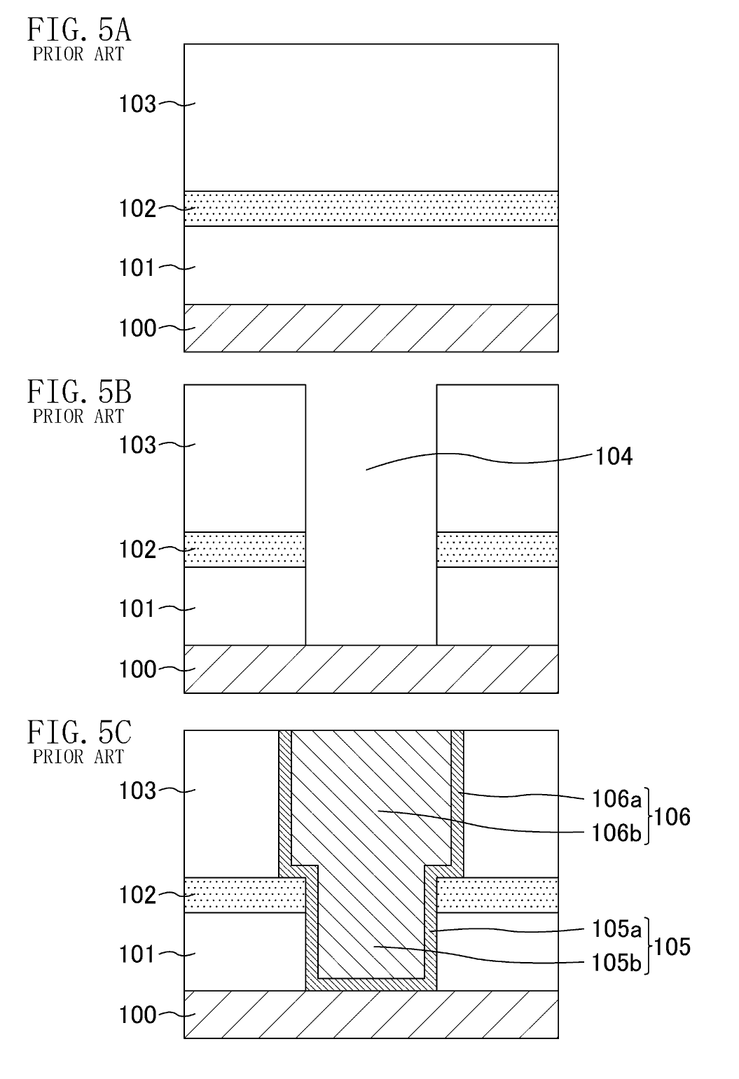

### DETAILED DESCRIPTION

An embodiment of the present invention will be described below with reference to the accompanying drawings.

### Embodiment

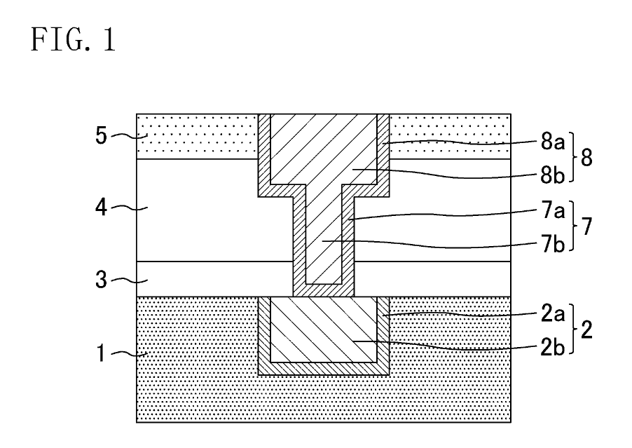

A semiconductor device according to an embodiment of the present invention will be described below with reference to FIGS. 1, 2A-2C, 3A-3C, and 4A-4B.

A configuration of the semiconductor device according to the embodiment of the present invention will be described with reference to FIG. 1. FIG. 1 is a cross-sectional view showing the configuration of the semiconductor device of the present embodiment.

As shown in FIG. 1, a first insulating film 1 is formed on a substrate (not shown). A first interconnect 2 having a barrier metal 2a and a conductive film 2b is formed in an upper region of the first insulating film 1. A second insulating film 3 including pores (not shown) is formed on the first insulating film 1 and the first interconnect 2.

A third insulating film 4 and a fourth insulating film 5 are sequentially formed on the second insulating film 3. A via 7 having a barrier metal 7a and a conductive film 7b is formed in both the second insulating film 3 and a lower region of the third insulating film 4. A second interconnect 8 having a barrier metal 8a and a conductive film 8b is formed in both an upper region of the third insulating film 4 and the fourth insulating film 5. The first and second interconnects 2, 8 are electrically connected together through the via 7.

The first insulating film 1 is made of, e.g., SiOC. As used herein, “SiOC” is a compound having a Si—O backbone with a —CH₃ group bonded thereto.

The second insulating film 3 (a liner film) is made of, e.g., SiC or SiCO, and has a relative dielectric constant of 4.0 or less. In the case where the second insulating film 3 is made of, e.g., SiCO, the atomic percentage of each atom forming the second insulating film 3 is, e.g., Si=38, O=35, and C=27 as measured by Rutherford backscattering spectrometry (RBS). As used herein, “SiC” is a compound having a Si—C backbone with a —CH₃ group bonded thereto, and “SiCO” is a compound having a Si—C backbone with O bonded thereto.

The third insulating film 4 is made of, e.g., SiOC, and has a relative dielectric constant of 2.5 or less.

The fourth insulating film 5 is made of, e.g., SiOC, and has a relative dielectric constant of 3.0.

The barrier metals 2a, 7a, and 8a are made of, e.g., tantalum nitride (TaN). The conductive films 2b, 7b, and 8b are made of, e.g., copper (Cu).

[Second Insulating Film (Liner Film)]

The second insulating film 3 is a liner film that is formed between the first insulating film 1 in which the first interconnect 2 is formed, and the third insulating film 4 in which the via 7 is formed. This liner film serves to prevent diffusion of a metal in the first interconnect 2 into the third insulating film 4.

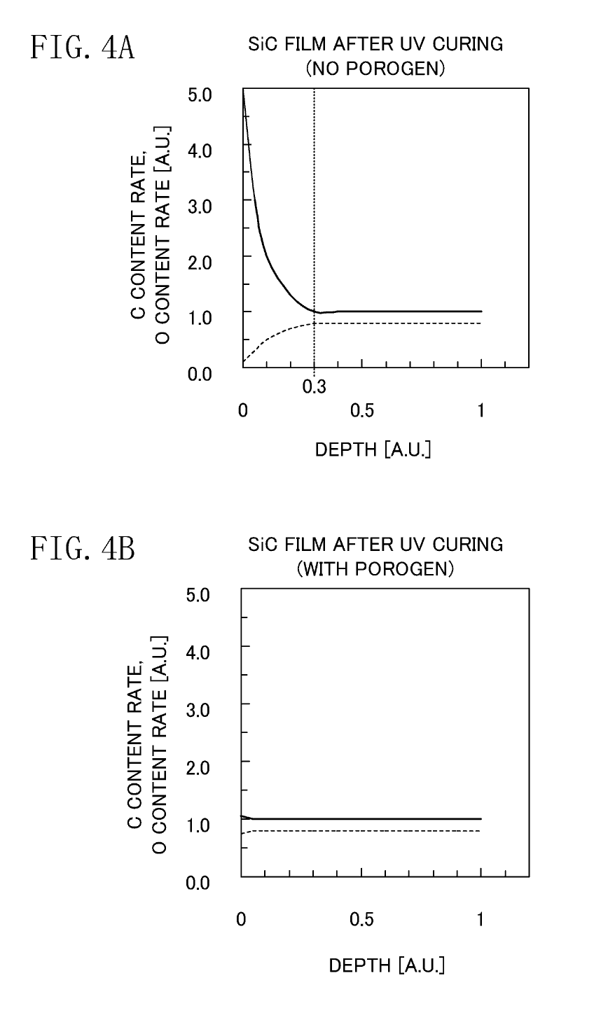

The inventor of the present application has found through examination that the second insulating film 3 has substantially the same carbon content rate in the thickness direction (see broken line in FIG. 4B described later), and that the second insulating film 3 has substantially the same oxygen content rate in the thickness direction (see solid line in FIG. 4B).

The second insulating film 3 has a density in the range of about 1.2 g/cm³ to about 2.0 g/cm³, both inclusive.

The Si—CH₃/Si—C ratio in the second insulating film 3 is in the range of 0.02 to 0.10, both inclusive.

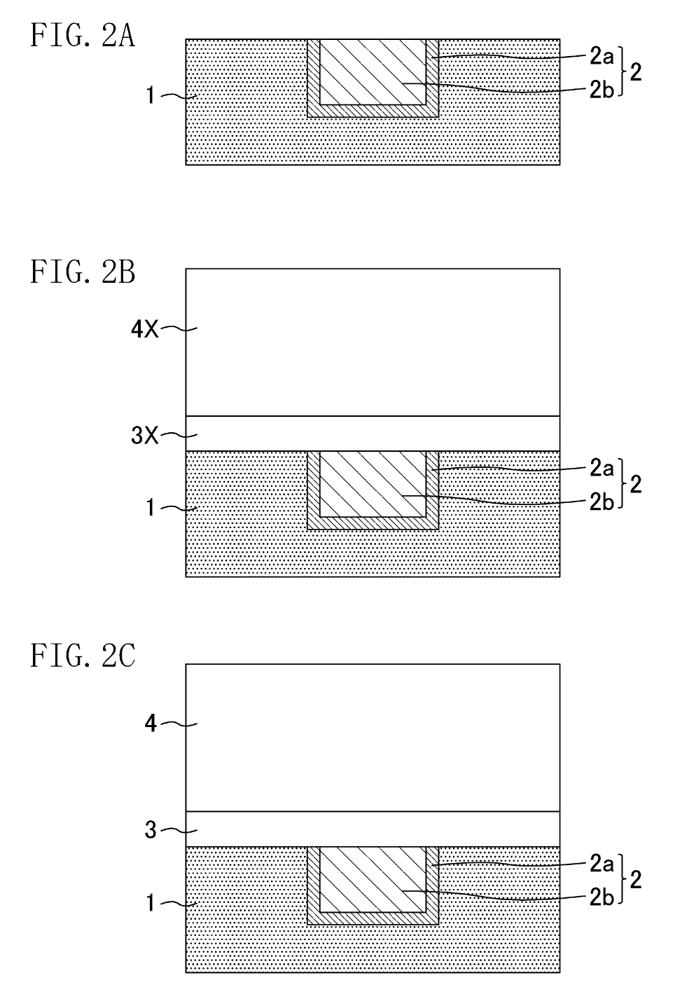

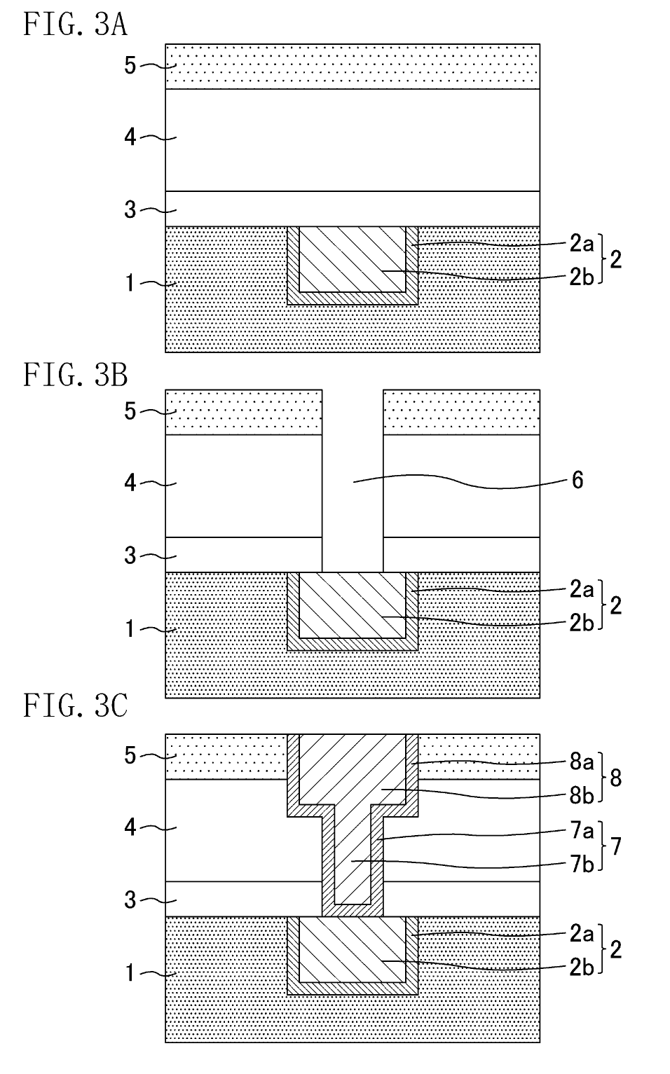

A method for manufacturing the semiconductor device according to the embodiment of the present invention will be described below with reference to FIGS. 2A-2C and 3A-3C. FIGS. 2A-3C are cross-sectional views sequentially showing the steps of the manufacturing method of the semiconductor device according to the present embodiment.

First, as shown in FIG. 2A, a first insulating film 1 made of, e.g., SiOC is formed on a substrate (not shown) made of, e.g., silicon. Next, a resist (not shown) is formed on the first insulating film 1, and an interconnect groove pattern is formed in the resist by a lithography method, thereby forming a resist pattern having the interconnect groove pattern. By using the resist pattern as a mask, dry etching is performed to form an interconnect groove in an upper region of the first insulating film 1, and the resist pattern is removed by ashing. Thereafter, a barrier metal made of, e.g., TaN is formed on the bottom and side surfaces of the interconnect groove and on the first insulating film 1 by a sputtering method, and a conductive film made of, e.g., Cu is formed above the first insulating film 1 by an electroplating method so as to fill the interconnect groove. Those portions of the barrier metal and the conductive film which are formed outside the interconnect groove are then removed by a CMP method, thereby forming a first interconnect 2. The first interconnect 2 has a barrier metal 2a formed on the bottom and side surfaces of the interconnect groove, and a conductive film 2b embedded in the interconnect groove with the barrier metal 2a interposed therebetween.

As shown in FIG. 2B, a second insulating film formation film 3X, which is made of, e.g., SiC with a thickness of 50 nm and contains porogen (not shown), is formed on the first insulating film 1 and the first interconnect 2 by, e.g., a chemical vapor deposition (CVD) method by using a gas containing organosilane, porogen, etc. as a source gas. The second insulating film formation film 3X has a relative dielectric constant of 5.0 or less.

Then, a third insulating film 4X, which is made of, e.g., SiOC with a thickness of 125 nm, is formed on the second insulating film formation film 3X by a CVD method. The third insulating film 4X has a relative dielectric constant of 3.0 or less.

As shown in FIG. 2C, the third insulating film 4X is irradiated with UV light to cure a third insulating film 4 (hereinafter referred to as the “UV curing process”). Specifically, for example, the third insulating film 4X is irradiated with UV light in a gas atmosphere such as helium (He) or argon (Ar) in a vacuum chamber having a UV light source placed therein. The third insulating film 4 thus formed has a relative dielectric constant of 2.5 or less.

The UV light in the UV curing process transmits through the third insulating film 4X. Thus, the UV light that has transmitted through the third insulating film 4X enters the second insulating film formation film 3X, whereby the second insulating film formation film 3X is subjected to the UV curing process. As a result, porogen contained in the second insulating film formation film 3X is eliminated in the UV curing process, whereby a second insulating film 3 includes pores (not shown) formed by the elimination of porogen. The second insulating film 3 thus formed has a relative dielectric constant of 4.0 or less.

In the step of FIG. 2C, the second insulating film 3 is formed so as to have a substantially constant carbon content rate in the thickness direction (see broken line in FIG. 4B described later), and so as to have a substantially constant oxygen content rate in the thickness direction (see solid line in FIG. 4B).

In the step of FIG. 2C, the second insulating film 3 has a density in the range of about 1.2 g/cm³ to about 2.0 g/cm³, both inclusive.

In the step of FIG. 2C, the Si—CH₃/Si—O ratio in the second insulating film 3 is in the range of 0.02 to 0.10, both inclusive.

The C/Si composition ratio in the second insulating film 3 is reduced from that in the second insulating film formation film 3X by 0.5% or more.

For example, the UV curing process is performed under the following conditions. Temperature: in the range of 300° C. to 450° C., both inclusive; pressure: in the range of 10×10⁻⁸ Pa to 1.01325×10⁵ Pa, both inclusive: atmosphere: atmosphere containing nitrogen; UV power: in the range of 1 kW to 10 kW, both inclusive; and UV radiation time: in the range of 240 seconds to 1,200 seconds, both inclusive.

Then, as shown in FIG. 3A, a fourth insulating film 5, which is made of, e.g., SiOC with a thickness of 60 nm, is formed on the third insulating film 4.

As shown in FIG. 3B, a resist (not shown) is then formed on the fourth insulating film 5, and a via hole pattern is formed in the resist by a lithography method, thereby forming a resist pattern having the via hole pattern.

By using the resist pattern as a mask, first dry etching is performed to remove those portions of the fourth insulating film 5 and the third insulating film 4 which are exposed in the via hole pattern of the resist pattern, thereby forming a hole that extends through the fourth insulating film 5 and the third insulating film 4 and exposes the upper surface of the second insulating film 3. Then, second dry etching is performed to remove a portion of the second insulating film 3 which is exposed in the hole, thereby forming a hole 6 that extends through the fourth insulating film 5, the third insulating film 4, and the second insulating film 3 and exposes the upper surface of the first interconnect 2. Thus, the second insulating film 3 functions as an etching stopper film. Thereafter, the resist pattern is removed by ashing.

As shown in FIG. 3C, a resist (not shown) is formed on the fourth insulating film 5, and an interconnect groove pattern is formed in the resist by a lithography method, thereby forming a resist pattern having the interconnect groove pattern. By using the resist pattern as a mask, dry etching is performed to form an interconnect groove in both an upper region of the third insulating film 4 and the fourth insulating film 5. The resist pattern is then removed by ashing. Thus, a via hole exposing the upper surface of the first interconnect 2 is formed in both the second insulating film 3 and a lower region of the third insulating film 4, and an interconnect groove communicating with the via hole is formed in both the upper region of the third insulating film 4 and the fourth insulating film 5.

Then, a barrier metal made of, e.g., TaN is formed on the bottom and side surfaces of the via hole, on the bottom and side surfaces of the interconnect groove, and on the fourth insulating film 5 by a sputtering method, and a conductive film made of, e.g., Cu is formed above the fourth insulating film 5 by an electroplating method so as to fill the via hole and the interconnect groove. Those portions of the barrier metal and the conductive film which are formed outside the interconnect groove are then removed by a CMP method, thereby forming a via 7 and a second interconnect 8. The via 7 has a barrier metal 7a formed on the bottom and side surfaces of the via hole, and a conductive film 7b embedded in the via hole with the barrier metal 7a interposed therebetween. The second interconnect 8 has a barrier metal 8a formed on the bottom and side surfaces of the interconnect groove, and a conductive film 8b embedded in the interconnect groove with the barrier metal 8a interposed therebetween.

The semiconductor device of the present embodiment can be formed in this manner.

Note that the present embodiment is specifically described with respect to an example in which the second insulating film 3 has a thickness of 50 nm, the third insulating film 4 has a thickness of 125 nm, and the fourth insulating film 5 has a thickness of 60 nm. However, it should be understood that the respective thicknesses of the second, third, and fourth insulating films are not limited to these. Since the second insulating film 3 is a liner film, the ratio of the total thickness of the third and fourth insulating films 4, 5 to the thickness of the second insulating film 3 is preferably in the range of about 0.5 to about 24, both inclusive. Thus, each of the second, third, and fourth insulating films 3, 4, and 5 preferably has a thickness that satisfies the ratio in the above range.

Note that the present embodiment is specifically described with respect to an example in which an insulating film in which the via 7 and the second interconnect 8 are formed is a stacked film formed by sequentially stacking the third insulating film 4 and the fourth insulating film 5. However, the insulating film may be a single-layer film.

Physical properties of the second insulating film 3 (i.e., the SiC film containing porogen and subjected to the UV curing process) will be described below with reference to FIGS. 4A-4B and Tables 1, 2, 3, 4, and 5.

[C Content Rate and O content Rate]

The relation between the respective content rates of C and O and the depth after the UV curing process of a SiC film containing no porogen and a SiC film containing porogen will be described with reference to FIGS. 4A-4B. FIG. 4A is a graph showing the relation between the respective content rates of C and O and the depth after the UV curing process of the SiC film containing no porogen. FIG. 4B is a graph showing the relation between the respective content rates of C and O and the depth after the UV curing process of the SiC film containing porogen.

In FIGS. 4A-4B, solid line represents the O content rate, and broken line represents the C content rate.

The abscissa in FIGS. 4A-4B represents the depth. As used herein, the “depth X” represents the depth from the upper surface, where the depth “0” is the level of the upper surface (i.e., the surface of the SiC film that is irradiated with UV light) of the SiC film after the UV curing process, and the depth “1” represents the level of the lower surface of the SiC film after the UV curing process.

The ordinate in FIGS. 4A-4B represents the C content rate or the O content rate. As used herein, the “C content rate” is the C content at the depth X relative to the C content at the depth “1,” and the “O content rate” is the O content at the depth X relative to the O content at the depth “1.”

As shown in FIG. 4A, in the case where the UV curing process is performed on the SiC film containing no porogen, the C content rate decreases as the depth becomes closer to “0” (in other words, toward the upper surface), while the O content rate increases as the depth becomes closer to “0.”

On the other hand, in the case where the UV curing process is performed on the SiC film containing porogen, both the C content rate and the O content rate are substantially constant as shown in FIG. 4B.

This result shows that, in the SiC film containing no porogen, Si—O bonds are formed near the upper surface (i.e., the surface of the SiC film that is irradiated with UV light) of the SiC film by the UV curing process, whereas in the SiC film containing porogen, no Si—O bonds are formed near the upper surface of the SiC film by the UV curing process.

When the SiC film containing porogen is subjected to the UV curing process, UV energy is consumed by eliminating porogen contained in the SiC film. Thus, no Si—O bonds are formed near the upper surface of the SiC film by the UV curing process. Accordingly, the C content rate and the O content rate in the SiC film do not vary in the thickness direction (the depth direction) by the UV curing process (see FIG. 4A), whereby the C content rate and the O content rate in the SiC film can be made substantially constant in the thickness direction.

[Relative Dielectric Constant]

The relative dielectric constants before and after the UV curing process of the SiC film containing no porogen and the SiC film containing porogen will be described below with reference to Table 1. The porosities before and after the UV curing process of the SiC film containing porogen will also be described below with reference to Table 2. The left side of Table 1 shows the relative dielectric constant before the UV curing process, the relative dielectric constant after the UV curing process, and the difference therebetween in the SiC film containing no porogen. The right side of Table 1 shows the relative dielectric constant before the UV curing process, the relative dielectric constant after the UV curing process, and the difference therebetween in the SiC film containing porogen. Table 2 shows the porosity before the UV curing process and the porosity after the UV curing process in the SiC film containing porogen. As used herein, the “porosity” refers to the proportion of the volume of pores to the total volume of the SiC film.

TABLE 1

| | No porogen | With porogen |
|---|---|---|
| Relative dielectric constant | 4.7 | 4.6 |
| before curing process | | |
| [a.u.] | | |
| Relative dielectric constant | 5.1 | 3.4 |
| after curing process | | |
| [a.u.] | | |
| Difference | +0.4 | −1.2 |

TABLE 2

| | Before curing process | After curing process |
|---|---|---|
| Porosity (%) | 0 | 21.4 |

As shown on the left side of Table 1, the SiC film containing no porogen has a higher relative dielectric constant after the UV curing process than before the UV curing process. This is because Si—O bonds are formed near the upper surface of the SiC film by the UV curing process, as can be seen from FIG. 4A.

On the other hand, as shown on the right side of Table 1, the SiC film containing porogen has a lower relative dielectric constant after the UV curing process than before the UV curing process. The relative dielectric constant after the UV curing process does not become higher than that before the UV curing process because no Si—O bonds are formed near the upper surface of the SiC film by the UV curing process, as can be seen from FIG. 4B. Moreover, as shown in Table 2, porogen contained in the SiC film is eliminated in the UV curing process, whereby pores are formed in the SiC film. Thus, the relative dielectric constant after the UV curing process is lower than that before the UV curing process.

When the SiC film containing porogen is subjected to the UV curing process, UV energy is consumed by eliminating porogen contained in the SiC film. Thus, no Si—O bonds are formed near the upper surface of the SiC film by the UV curing process. Accordingly, the relative dielectric constant after the UV curing process can be prevented from becoming higher than that before the UV curing process as shown in Table 1.

Moreover, as shown in Table 2, porogen contained in the SiC film can be eliminated by the UV curing process, whereby the resultant SiC film includes pores formed by the elimination of porogen. Thus, the relative dielectric constant after the UV curing process can be made lower than that before the UV curing process, as shown in Table 1.

[Rate of Change in Stress]

The rate of change in stress before and after the UV curing process in the SiC film containing no porogen and the SiC film containing porogen will be described with reference to Table 3. The left side of Table 3 shows the rate of change in stress before and after the UV curing process in the SiC film containing no porogen, and the right side of Table 3 shows the rate of change in stress before and after the UV curing process in the SiC film containing porogen. As used herein, the “rate of change in stress before and after the UV curing process” is calculated by the following equation, where “Sb” represents stress in the SiC film before the UV curing process, and “Sa” represents stress in the SiC film after the UV curing process.

Rate of change in stress before and after UV curing process=(Sa−Sb)/Sb

TABLE 3

| | No porogen | With porogen |
|---|---|---|
| Rate of change in stress | 1 | 0.83 |
| before and after curing process | | |
| [a.u.] | | |

The above result shows that tensile stress is generated in both the SiC film containing no porogen and the SiC film containing porogen after the UV curing process.

In the case where the rate of change in stress in the SiC film containing no porogen is 1, the rate of change in stress in the SiC film containing porogen is 0.83.

This shows that relatively high tensile stress is generated after the UV curing process in the SiC film containing no porogen. This is because Si—O bonds are formed near the upper surface of the SiC film by the UV curing process, as can be seen from FIG. 4A, and the difference between stress in the upper surface of the SiC film and stress in the lower surface of the SiC film becomes relatively large.

The above result also shows that relatively low tensile stress is generated after the UV curing process in the SiC film containing porogen. This is because no Si—O bonds are formed near the upper surface of the SiC film by the UV curing process, as can be seen from FIG. 4B, and the difference between stress in the upper surface of the SiC film and stress in the lower surface of the SiC film does not become relatively large.

When the SiC film containing porogen is subjected to the UV curing process, UV energy is consumed by eliminating porogen contained in the SiC film. Thus, no Si—O bonds are formed near the upper surface of the SiC film by the UV curing process. Accordingly, as shown in Table 3, high tensile stress is not generated in the SiC film by the UV curing process, whereby generation of high tensile stress in the SiC film can be suppressed.

[50% Failure Time]

The relation between stress in the SiC film and electrical characteristics of an interconnect formed below the SiC film will be described with reference to Table 4. Table 4 shows the relation between stress in the SiC film and failure associated with electromigration (EM) of the interconnect. In Table 4, “50% failure time” represents a mean time to failure of interconnect elements. In Table 4, “−100 [MPa]” means compressive stress of 100 [MPa], and “+300 [MPa] means tensile stress of 300 [MPa].

TABLE 4

| Stress in SiC film [MPa] | −100 | +300 |
|---|---|---|
| 50% Failure Time [a.u.] | 1 | 0.14 |

As shown in Table 4, if the 50% failure time is 1 in the case where the stress in the SiC film is compressive stress of 100 MPa, the 50% failure time is 0.14 in the case where the stress in the SiC film is tensile stress of 300 MPa.

The result of Table 4 shows that the 50% failure time is shorter in the case where the stress in the SiC film is tensile stress than in the case where the stress in the SiC film is compressive stress. The reason for this is as follows. In the case where the stress in the SiC film is tensile stress, the SiC film is subjected to tensile stress in the upward direction (the direction away from the interconnect). This reduces adhesion between the interconnect and the SiC film, whereby a void is formed between the SiC film and the interconnect by an EM test of the interconnect. Thus, the 50% failure time is shorter in the case where the stress in the SiC film is tensile stress than in the case where the stress in the SiC film is compressive stress.

That is, since a failure is less likely to occur at lower tensile stress, the SiC film containing porogen and subjected to the UV curing process is more preferable than the SiC film containing no porogen and subjected to the UV curing process.

[Capacitance Between Interconnects]

Capacitance between interconnects in a semiconductor device manufactured by using the SiC film containing no porogen as the second insulating film formation film and a semiconductor device (the semiconductor device of the present embodiment) manufactured by using the SiC film containing porogen as the second insulating film formation film will be described with reference to Table 5. Table 5 shows the capacitance between interconnects in the semiconductor device manufactured by using the SiC film containing no porogen, and the capacitance between interconnects in the semiconductor device manufactured by using the SiC film containing porogen.

TABLE 5

| | No porogen | With porogen |
|---|---|---|
| Capacitance between interconnects [pF] | 1.15 × 10⁻¹ | 1.05 × 10⁻¹ |

As shown in Table 5, the capacitance between interconnects in the semiconductor device manufactured by using the SiC film containing porogen can be reduced by about 10% from that in the semiconductor device manufactured by using the SiC film containing no porogen.

According to the present embodiment, even if UV light transmits through the third insulating film 4X and enters the second insulating film formation film 3X formed below the third insulating film 4X in the UV curing process, UV energy that has entered the second insulating film formation film 3X can be consumed by eliminating porogen contained in the second insulating film formation film 3X. Thus, no Si—O bonds are formed near the upper surface of the second insulating film 3 by the UV light that has entered the second insulating film formation film 3X, whereby an increase in relative dielectric constant of the second insulating film 3 can be prevented (Table 1). As a result, an increase in capacitance between interconnects, and an increase in interconnect delay can be prevented.

As described above, no Si—O bonds are formed near the upper surface of the second insulating film 3 by the UV light that has entered the second insulating film formation film 3X. This can suppress generation of high tensile stress in the second insulating film 3 (see Table 3), and thus can suppress reduction in adhesion between the second insulating film 3 and the first interconnect 2 formed below the second insulating film 3, thereby suppressing reduction in interconnect reliability.

Moreover, since porogen contained in the second insulating film formation film 3X is eliminated in the UV curing process, the second insulating film 3 has pores formed by the elimination of porogen. Thus, the relative dielectric constant of the second insulating film 3 can be reduced (see Table 1), whereby the capacitance between interconnects can be reduced (see Table 5).

Note that the present embodiment is specifically described with respect to an example in which the third insulating film 4 is irradiated with UV light as the curing process. However, the present invention is not limited to this.

As a first example, the third insulating film may be irradiated with electron beams as the curing process. For example, the electron beam radiation is performed under the following conditions. Temperature: in the range of 300° C. to 450° C., both inclusive; pressure: in the range of 10×10⁻⁸ Pa to 10×10⁻⁴ Pa, both inclusive; atmosphere: atmosphere containing helium; electron beam power: in the range of 10 kW to 30 kW, both inclusive; and electron beam radiation time: in the range of 60 seconds to 180 seconds, both inclusive.

As a second example, the third insulating film may be exposed to a heat source as the curing process. For example, the exposure to the heat source may be performed under the following conditions. Temperature: in the range of 600° C. to 1,200° C., both inclusive; pressure: in the range of 10×10⁻⁴ Pa to 1.01325×10⁵ Pa, both inclusive; atmosphere: atmosphere containing helium, nitrogen, or hydrogen; and exposure time: in the range of 10 minutes to 30 minutes, both inclusive.

The present embodiment is specifically described with respect to an example in which the second insulating film 3 made of SiC is formed by using the second insulating film formation film 3X made of SiC. However, the present invention is not limited to this.

[SiCO]

As a first example, the second insulating film made of SiCO may be formed by using the second insulating film formation film made of SiCO. As used herein, “SiCO” represents a compound having a Si—C backbone with O bonded thereto.

For example, the second insulating film formation film made of SiCO is formed by a CVD method under the following conditions. Deposition temperature: 200 to 300° C.; tetramethylsilane: 300 sccm (standard cubic centimeter per minute); carbon dioxide (CO₂): 1,900 sccm; cyclic C₁₀H₁₆: 800 sccm; helium (He): 1,500 to 3,000 sccm; deposition pressure: 533 Pa; radio frequency (RF) power: 450 W (high frequency: 27.1 MHz); and RF power: 100 W (low frequency: 13.56 MHz).

The second insulating film has a density of about 1.2 g/cm³ to about 2.0 g/cm³, both inclusive.

The Si—O/Si—C ratio in the second insulating film is 1.0 or more.

The C/Si composition ratio in the second insulating film is reduced from that in the second insulating film formation film by 0.5% or more.

The O/Si composition ratio in the second insulating film is increased from that in the second insulating film formation film by 2.0% or more.

[SiCN]

As a second example, the second insulating film made of SiCN may be formed by using the second insulating film formation film made of SiCN. As used herein, “SiCN” represents a compound having a Si—C backbone with N bonded thereto.

For example, the second insulating film formation film made of SiCN is formed by a CVD method under the following conditions. Deposition temperature: 200 to 300° C.; tetramethylsilane: 220 sccm; ammonia (NH₃): 250 sccm; cyclic C₁₀H₁₆: 800 sccm; He: 1,500 to 3,000 sccm; deposition pressure: 665 Pa; RF power: 550 W (high frequency: 27.1 MHz); and RF power: 70 W (low frequency: 13.56 MHz).

The second insulating film has a density of about 1.2 g/cm³ to about 2.0 g/cm³, both inclusive.

The C/Si composition ratio in the second insulating film is reduced from that in the second insulating film formation film by 0.5% or more.

The N/Si composition ratio in the second insulating film is reduced from that in the second insulating film formation film by 2.0% or more.

The present embodiment is specifically described with respect to an example in which the second insulating film 3 is a SiC film. However, the present invention is not limited to this. For example, a SiCN film may be formed at the upper or lower surface of the second insulating film.

As described above, in the curing process of a film, no unnecessary bonds (e.g., Si—O bonds) are formed near the upper surface of a film formed below the film, whereby an increase in interconnect delay can be prevented, and reduction in interconnect reliability can be suppressed. Thus, the present invention is useful for semiconductor devices having a film that is subjected to a curing process, and a manufacturing method thereof.

What is claimed is:

1. A semiconductor device, comprising:
a first insulating film formed on a substrate and having a first interconnect;
a second insulating film as a liner film formed on the first insulating film and the first interconnect so as to contact the first insulating film; and
a third insulating film formed on the second insulating film so as to contact the second insulating film, wherein
the second insulating film includes pores.

2. The semiconductor device of claim 1, wherein
the third insulating film is made of SiOC, and
the third insulating film has a relative dielectric constant of 2.5 or less.

3. The semiconductor device of claim 1, further comprising:
a fourth insulating film formed on the third insulating film, wherein
a via is formed in both the second insulating film and a lower region of the third insulating film,
a second interconnect is formed in both an upper region of the third insulating film and the fourth insulating film, and
the first interconnect is electrically connected to the second interconnect through the via.

4. The semiconductor device of claim 3, wherein
the second insulating film is thinner than the third insulating film.

5. The semiconductor device of claim 3, wherein
a ratio of a total thickness of the third insulating film and the fourth insulating film to a thickness of the second insulating film is in a range of 0.5 to 24, both inclusive.

6. The semiconductor device of claim 1, wherein
the second insulating film is made of SiC.

7. The semiconductor device of claim 1, wherein
the second insulating film has a relative dielectric constant of 4.0 or less.

8. The semiconductor device of claim 1, wherein
the second insulating film has a substantially constant carbon content rate in a thickness direction.

9. The semiconductor device of claim 1, wherein
the second insulating film has a substantially constant oxygen content rate in a thickness direction.

10. The semiconductor device of claim 1, wherein
the second insulating film has a density of about 1.2 g/cm³ to about 2.0 g/cm³, both inclusive.

11. The semiconductor device of claim 1, wherein
a Si—CH₃/Si—C ratio in the second insulating film is in a range of 0.02 to 0.10, both inclusive.

12. The semiconductor device of claim 1, wherein
the second insulating film is made of SiCO, and
a Si—O/Si—C ratio in the second insulating film is 1.0 or more.

13. The semiconductor device of claim 1, wherein
the second insulating film is made of SiCN.

14. A method for manufacturing a semiconductor device, comprising the steps of:
(a) forming on a substrate a first insulating film having a first interconnect;
(b) forming on the first insulating film and the first interconnect a second insulating film formation film containing porogen so that the second insulating film formation film contacts the first insulating film;
(c) forming a third insulating film on the second insulating film formation film so that the third insulating film contacts the second insulating film formation film; and
(d) performing a curing process on the third insulating film, wherein
in the step (d), the curing process is performed on the second insulating film formation film to form a second insulating film having pores formed by eliminating the porogen contained in the second insulating film formation film.

15. The method of claim 14, wherein
the third insulating film is made of SiOC, and
in the step (d), a relative dielectric constant of the third insulating film is reduced from that of the third insulating film in the step (c), and the relative dielectric constant of the third insulating film in the step (d) is 2.5 or less.

16. The method of claim 14, wherein
the step (d) is a step of irradiating the third insulating film with UV light.

17. The method of claim 14, wherein
the step (d) is a step of irradiating the third insulating film with electron beams.

18. The method of claim 14, wherein
the step (d) is a step of exposing the third insulating film to a heat source.

19. The method of claim 14, further comprising the steps of:
(e) after the step (d), forming a fourth insulating film on the third insulating film; and
(f) forming a via in a via hole formed in both the second insulating film and a lower region of the third insulating film, and forming a second interconnect in an interconnect groove formed in both an upper region of the third insulating film and the fourth insulating film.

20. The method of claim 14, wherein
the second insulating film is made of SiC.

21. The method of claim 14, wherein
in the step (d), a relative dielectric constant of the second insulating film is reduced from that of the second insulating film formation film, and the relative dielectric constant of the second insulating film is 4.0 or less.

22. The method of claim 14, wherein
in the step (d), the second insulating film is formed so as to have a substantially constant carbon content rate in a thickness direction.

23. The method of claim 14, wherein
in the step (d), the second insulating film is formed so as to have a substantially constant oxygen content rate in a thickness direction.

24. The method of claim 14, wherein
in the step (d), a C/Si composition ratio in the second insulating film is reduced from that in the second insulating film formation film by 0.5% or more.

25. The method of claim 14, wherein
the second insulating film is made of SiCO, and
in the step (d), an O/Si composition ratio in the second insulating film is increased from that in the second insulating film formation film by 2.0% or more.

26. The method of claim 14, wherein
the second insulating film is made of SiCN, and
in the step (d), an N/Si composition ratio in the second insulating film is reduced from that in the second insulating film formation film by 2.0% or more.
